(19) United States
(12) Patent Application Publication
(10) Pub. No.: US 2022/0181190 A1
(43) Pub. Date: Jun. 9, 2022

(54) WAFER FIXING MECHANISM AND WAFER PRE-CLEANING MACHINE USING THE WAFER FIXING MECHANISM

(71) Applicant: Skytech Co., Ltd., Hsinchu County (TW)

(72) Inventors: JING-CHENG LIN, Hsinchu County (TW); CHI-HUNG CHENG, Hsinchu County (TW); YU-TE SHEN, Hsinchu County (TW); YAO-SYUAN CHENG, Hsinchu County (TW)

(21) Appl. No.: 17/111,124

(22) Filed: Dec. 3, 2020

(51) Int. Cl. H01L 21/687; H01L 21/67; B08B 7/00

(52) U.S. Cl. CPC H01L 21/68721; B08B 7/0035; H01L 21/67034

(57) ABSTRACT

A wafer fixing mechanism as disclosed includes a fixing ring, a plurality of fixing members and a plurality of elastic units, wherein each fixing member is respectively connected to the fixing ring through a connecting shaft. The fixing ring includes a containing area for containing a wafer, and the wafer in the containing area is fixed by the fixing members. The two ends of the elastic unit are respectively connected to the fixing ring and the fixing member. When the wafer pushes the fixing members, the fixing members will swing relative to the fixing ring to prevent the fixing members from damaging the wafer. In addition, when the fixing member swings relative to the fixing ring, the elastic unit is deformed, so that the restoring force of the elastic unit is applied to the wafer via the fixing member, thereby fixing the wafer on a support pedestal.

### TECHNICAL FIELD

The present disclosure relates to a wafer fixing mechanism and a wafer pre-cleaning machine using the wafer fixing mechanism, more particularly, to a wafer fixing mechanism that is able to fix a wafer on a support pedestal without crushing the wafer, for preventing damage to the wafer during a wafer pre-cleaning process.

### BACKGROUND

Thin film deposition is a commonly employed technology for manufacturing semiconductors, and processes such as chemical vapor deposition (CVD) and physical vapor deposition (PVD) are mainly employed to form thin films on surfaces of wafers. In practical use, there may often be oxide layer or oxide on the surface of the wafer, which will affect the quality of the thin film deposition. Also, if there is any oxide layer or oxide between the deposited thin film and the wafer, this may greatly increase contact resistance and then raise a risk of damaging wafers.

To solve the aforementioned issues, the industries nowadays commonly proceed with a pre-clean process to the wafer before the deposition process, so as to remove the oxide layer or oxide on the surface of the wafer. Specifically, argon gas may be transferred into a reaction space and a magnetic field is applied to the reaction space, to generate argon plasma. Thereafter, negative pressure is provided on a support pedestal supporting the wafer, which then causes argon ions to hit the wafer and to remove the oxide layer or oxide on the surface of the wafer.

Generally, a fixing ring is used to fix the wafer on the support pedestal, wherein a fixing member on the fixing ring will contact and press fit on the surface of the wafer to prevent the wafer from moving relative to the support pedestal during the pre-clean process. However, the wafer usually is not completely flat, and therefore when the wafer is placed on the support pedestal, an edge area of the wafer may bulge upward. Hence, when the fixing member on the fixing ring is press fitted on the edge area of the wafer, this may cause the edge area of the wafer to be crushed, and further affect the yield of the wafer.

### SUMMARY

To solve the aforementioned issues, the present disclosure provides a novel wafer fixing mechanism and a wafer pre-cleaning machine using the novel wafer fixing mechanism, wherein fixing members of the wafer fixing device can swing relatively when receiving an external force greater than a threshold value, to prevent the fixing members from applying excessive pressure on and causing damage to the wafer.

An object of the present disclosure is to provide a wafer fixing mechanism, mainly including a fixing ring and a plurality of fixing members, wherein each of the fixing member is connected to the fixing ring via a connecting shaft, and is able to swing relative to the fixing ring. A plurality of elastic units is disposed between the fixing members and the fixing ring, wherein the elastic units can provide restoring force to the fixing members, and the fixing members can apply pressure on the wafer which is in a containing area of the fixing ring, to fix the wafer on a support pedestal.

Also, when fixing members are affected by an external force, such as being pressed by the wafer, the fixing members will swing relative to the fixing ring, and cause the elastic units to deform, wherein the elastic units may serve as a cushion between the fixing members and the wafer, and to prevent the fixing members from crushing the edge area of the wafer. Then, when the external force applied on the fixing members is gone, the fixing members will receive the restoring force from the elastic units and return to an original position.

An object of the present disclosure is to provide a wafer pre-cleaning machine mainly including a chamber, a wafer fixing mechanism and a support pedestal, wherein the wafer fixing mechanism and the support pedestal are positioned in a containing room of the chamber. The wafer fixing mechanism includes a fixing ring and at least three fixing members, wherein each of the fixing members is connected to the fixing ring via a connecting shaft which enables the fixing member to swing relative to the fixing ring. An elevating unit that is capable of carrying the support pedestal and a supported wafer to ascend, and allow the support pedestal to connect to the fixing ring, then the fixing members will contact and fix the wafer on the support pedestal. When a push force applied on the fixing members from the wafer is greater than a threshold value, the fixing members will swing relative to the fixing ring, to avoid crushing the edge area of the wafer.

To achieve the aforementioned objects, the present disclosure provides a wafer pre-cleaning machine including: a chamber that includes a containing room; at least one gas-extraction end that is fluidly connected to the containing room, for extracting gas within the containing room; at least one gas-inlet end that is fluidly connected to the containing room, for transferring cleaning gas to the containing room; at least one coil that is adjacent to the chamber and electrically connected to an alternative-current power source, wherein the coil is used to form a magnetic field in the containing room and transform the cleaning gas into plasma; a support pedestal that is positioned in the containing room for supporting at least one wafer, wherein the support pedestal is electrically connected to a bias power source to generate a bias on the support pedestal, and the bias causes the plasma to hit the wafer on the support pedestal so as to clean the wafer supported on the support pedestal; at least one fixing ring that is disposed in the containing room and includes a containing area wherein the wafer supported by the support pedestal is positioned in the containing area; a plurality of fixing members, each of the fixing members is connected to the fixing ring respectively via a connecting shaft and is able to swing relative to the fixing ring with the connecting shaft as an axis, wherein the fixing members contact a surface of the wafer, and fix the wafer on the support pedestal; and a plurality of elastic units, each of the elastic units is positioned between a respective one of the fixing members and the fixing ring, wherein when the wafer applies a push force to the fixing members, the fixing members will swing relative to the fixing ring, and cause the elastic units to deform.

The present disclosure further provides a wafer fixing mechanism including: a fixing ring that includes a containing area for containing a wafer; a plurality of fixing members, each of the fixing members is connected to the fixing ring respectively via a connecting shaft and is able to swing relative to the fixing ring with the connecting shaft as an axis, wherein the fixing members are used to contact and fix the wafer; and a plurality of elastic units, each of the elastic units is positioned between a respective one of the fixing members and the fixing ring, wherein when the wafer applies a push force to the fixing members, the fixing members will swing relative to the fixing ring, and cause the elastic units to deform.

### BRIEF DESCRIPTION OF THE DRAWINGS

The structure as well as preferred modes of use, further objects, and advantages of this present disclosure will be best understood by referring to the following detailed description of some illustrative embodiments in conjunction with the accompanying drawings, in which:

FIG. 1 is a side schematic view of a wafer pre-cleaning machine according to an embodiment of the present disclosure.

FIG. 2 is a perspective schematic view of a wafer-fixing structure and a support pedestal of the wafer pre-cleaning machine according to an embodiment of the present disclosure.

FIG. 3 is a perspective schematic view of a wafer-fixing structure of the wafer pre-cleaning machine according to an embodiment of the present disclosure.

FIG. 4 is a perspective fragmentary enlarged schematic view of a partial structure of the wafer pre-cleaning machine according to an embodiment of the present disclosure.

FIG. 5 is a fragmentary enlarged sectional schematic view of a partial structure of the wafer pre-cleaning machine according to an embodiment of the present disclosure.

FIG. 6 is a fragmentary enlarged side view of the wafer-fixing structure of the wafer pre-cleaning machine according to an embodiment of the present disclosure.

FIG. 7 is a fragmentary enlarged side view of the wafer-fixing structure of the wafer pre-cleaning machine according to an embodiment of the present disclosure.

FIG. 8 is a sectional schematic view of a wafer pre-cleaning machine according to another embodiment of the present disclosure.

FIG. 9 is a perspective schematic view of the swing-type wafer fixing mechanism of the wafer pre-cleaning machine according to another embodiment of the present disclosure.

FIG. 10 is a perspective exploded schematic view of a wafer-fixing structure of the wafer pre-cleaning machine according to another embodiment of the present disclosure.

FIG. 11 is a perspective exploded fragmentary enlarged schematic view of a partial structure of the wafer pre-cleaning machine according to another embodiment of the present disclosure.

FIG. 12 is a perspective fragmentary enlarged sectional schematic view of a partial structure of the wafer pre-cleaning machine according to another embodiment of the present disclosure.

FIG. 13 is a fragmentary enlarged sectional schematic view of a partial structure of the wafer pre-cleaning machine according to another embodiment of the present disclosure.

FIG. 14 is a fragmentary enlarged sectional schematic view of a partial structure of the wafer pre-cleaning machine according to another embodiment of the present disclosure.

### DETAILED DESCRIPTION OF THE PREFERRED EMBODIMENTS

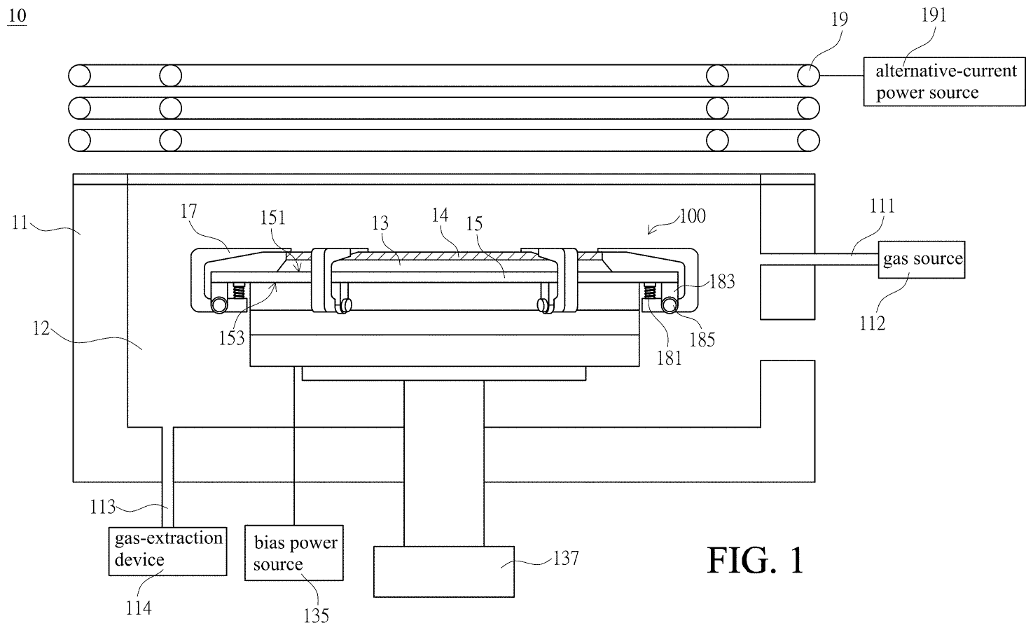

FIG. 1 is a side schematic view of a wafer pre-cleaning machine 10 according to an embodiment of the present disclosure. As shown, the wafer pre-cleaning machine 10 mainly includes a chamber 11, a support pedestal 13, a wafer-fixing structure 100, and a coil 19. The chamber 11 has a containing room 12, and the support pedestal 13 and the wafer-fixing structure 100 are positioned in the containing room 12 of the chamber 11. The support pedestal 13 is used for placing at least one wafer 14, and the wafer-fixing structure 100 is used for fixing the wafer 14 on the support pedestal 13.

The chamber 11 has at least one gas inlet end 111 and one gas-extraction end 113, wherein the gas inlet end 111 and the gas-extraction end 113 are fluidly connected to the containing room 12 of the chamber 11. The gas-extraction end 113 can be connected to a gas-extraction device 114, for extracting gas within the containing room 12. The gas inlet end 111 is connectable to a gas source 112, wherein the gas source 112 can serve as a container for storing a cleaning gas, and transfer the cleaning gas into the containing room 12 through the gas inlet end 111. For example, the cleaning gas may be argon gas or other noble gas, and the gas-extraction device 114 may be a pump which can extract the gas within the containing room 12 before, during and/or after the pre-cleaning.

The coil 19 is electrically connected to an alternative-current power source 191, wherein the alternative-current power source 191 provides an alternative-current electricity to the coil 19, and thus the coil 19 forms a magnetic field in the containing room 12 of the chamber 11. Affected by the magnetic field, the cleaning gas in the containing room 12 generates plasma, such as transforming argon gas into argon ions. The coil 19 is adjacent to the chamber 11, and above or aside of the chamber 11, basically just sufficient for the coil 19 to generate magnetic field in the containing room 12 of the chamber 11 to form plasma within the containing room 12, therefore position of the coil 19 is not limited by the scope of the present disclosure.

The support pedestal 13 is used to support at least one wafer 14. The support pedestal 13 is electrically connected to a bias power source 135, wherein the bias power source 135 is used for forming a bias on the support pedestal 13 and causing the plasma to hit the wafer 14 on the support pedestal 13, and the bias power source 135 may, for example, be an alternative-current power source or a direct-current power source. To be specific, the support pedestal 13 may be a conductor, and the bias power source 135 is used to form negative voltage on the support pedestal 13, to attract positive-charged argon ions (Ar+), which causes the argon ions to hit the wafer 14 on the support pedestal 13, thereby removing an oxide layer and/or oxide on the surface of the wafer 14, in order to pre-clean the wafer 14.

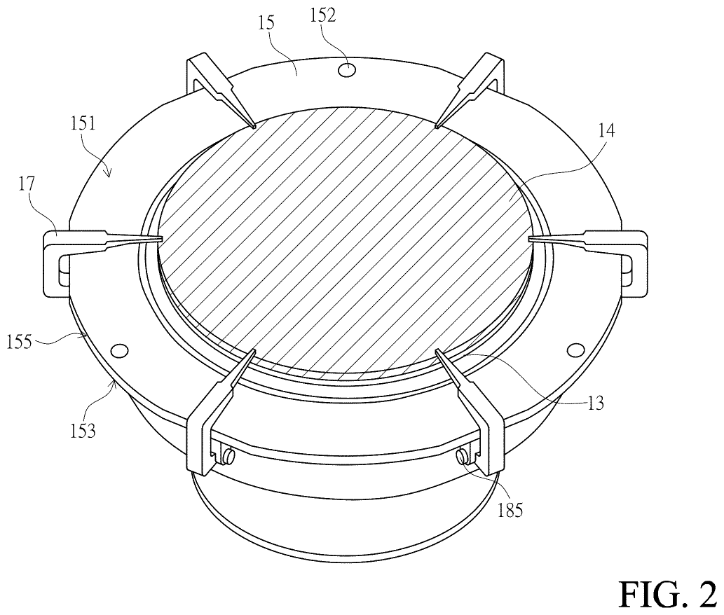

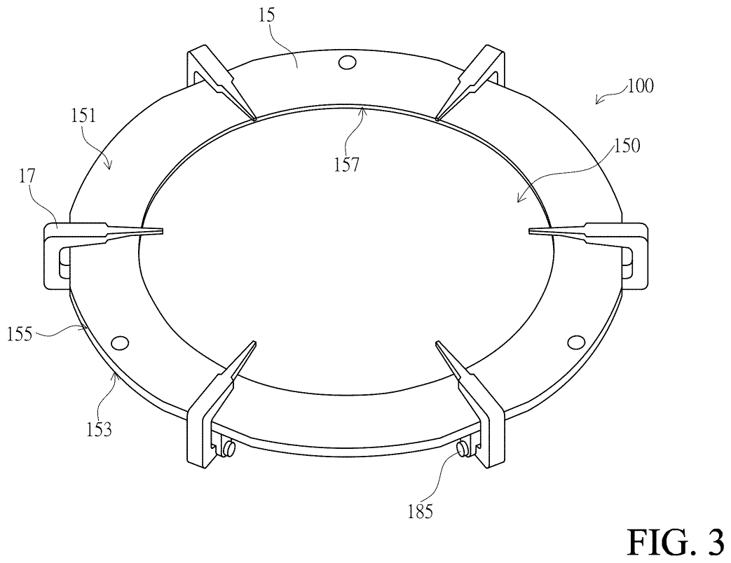

The wafer-fixing structure 100 includes a fixing ring 15 and a plurality of fixing members 17, as shown in FIG. 2 and FIG. 3. The fixing ring 15 includes an upper surface 151, a lower surface 153, an outer surface 155 and an inner surface 157, wherein the upper surface 151 and the lower surface 153 may be an annular structure. The outer surface 155 and the inner surface 157 are side surfaces interconnecting the upper surface 151 and the lower surface 153, wherein a top view of the outer surface 155 and the inner surface 157 is approximate to a round-shape, and a radius of the outer surface 155 is greater than that of the inner surface 157. The inner side of the inner surface 157 of the fixing ring 15 may form a containing area 150, wherein the support pedestal 13 and the wafer 14 may be positioned in the containing area 150 of the fixing ring 15.

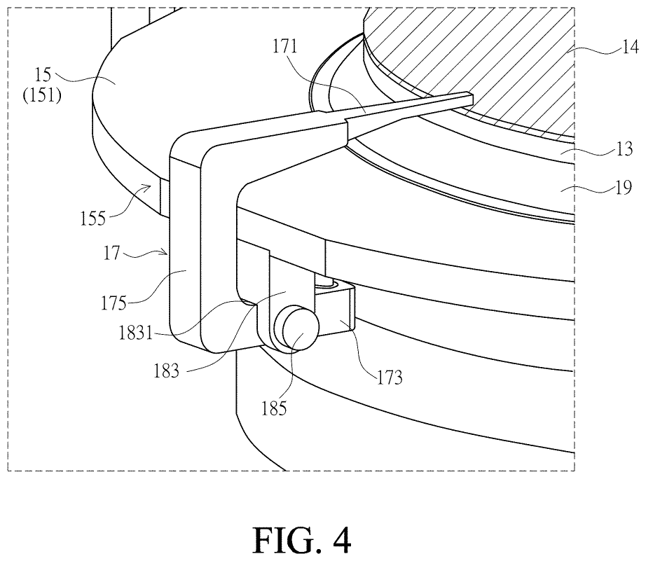

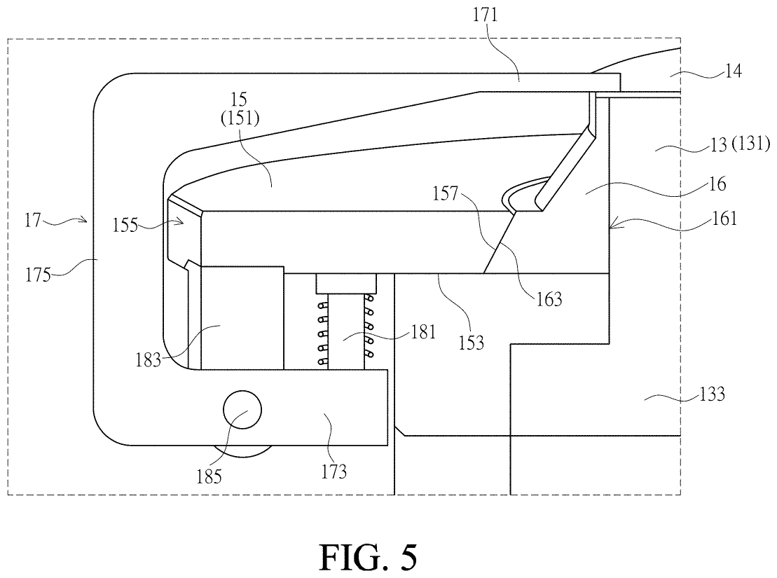

As shown in FIG. 4 and FIG. 5, each of the fixing members 17 is connected to the fixing ring 15 respectively via a connecting shaft 185. The number of the fixing member 17 may be three or more, and the fixing members 17 are swingable relative to the fixing ring 15 with the connecting shafts 185 as the axis. The fixing members 17 positioned on the upper surface 151 of the fixing ring 15 extend in a direction from the outer surface 155 of the fixing ring 15 toward the inner surface 157, and protrude on the inner surface 157 of the fixing ring 15 such that the fixing members 17 are partially at a position perpendicularly extending from the containing area 150. In one embodiment of the present disclosure, an appearance of the fixing ring 15 is approximately annular, and the fixing members 17 extend along a radical direction of the fixing ring 15.

The fixing ring 15 can be connected to the support pedestal 13 and is positioned to surround the support pedestal 13 with or without the wafer 14. When the fixing ring 15 is disposed on the support pedestal 13, the fixing members 17 connecting to the fixing ring 15 will contact the wafer 14 which is supported by the support pedestal 13, thereby fixing the wafer 14 on the support pedestal 13.

To prevent the fixing members 17 from applying excessive pressure on the wafer 14 and damaging the wafer 14 during the process of fixing the wafer 14 on the support pedestal 13, the fixing members 17 of the present disclosure is swingable relative to the fixing ring 15 such as to swing upward. Moreover, a plurality of elastic units 181 are disposed between the fixing members 17 and the fixing ring 15, for example, the elastic units 181 may be coil springs or plate springs. Each of the elastic units 181 has an end connected to a respective one of the fixing members 17, and another end connected to the fixing ring 15. When the wafer 14 is applying a push force on the fixing members 17, the fixing members 17 will swing relative to the fixing ring 15, and cause the elastic units 181 between the fixing members 17 and the fixing ring 15 to deform. Restoring force generated by the deformed elastic units 181 will be transferred to the wafer 14 through the fixing members 17, for fixing the wafer 14 on the support pedestal 13.

In practical use, elastic units 181 with suitable restoring force may be chosen, in accordance with a maximum tolerable external force for the wafer 14 and a critical external force sufficient to move the wafer 14. This enables the force transferred from the elastic units 181 to the wafer 14 through the fixing members 17 to fix the wafer 14 on the support pedestal 13, without damaging the wafer 14.

In one embodiment of the present disclosure, the fixing ring 15 includes a plurality of connecting arms 183, and for example, each of the connecting arms 183 may be disposed on the lower surface 153 of fixing ring 15 and be connected to the fixing members 17 via the connecting shaft 185. To be specific, each of the connecting arms 183 has an end connected to the lower surface 153 of the fixing ring 15, and another end connected to a respective one of the fixing members 17, wherein the end connected to the fixing members 17 may be disposed with a block portion 1831 to restrain a swinging angle of the fixing members 17 relative to the fixing ring 15.

Appearances of the fixing members 17 may be approximate to U-shape as shown in FIG. 4 and FIG. 5, and each of the fixing members 17 includes a first end 171, a second end 173, and a connecting portion 175. Two ends of the connecting portion 175 are respectively connected to the first end 171 and the second end 173, to form those approximately U-shaped fixing members 17. The fixing members 17 are disposed next to the fixing ring 15, wherein the first ends 171 thereof are positioned on one side of the upper surface 151 of the fixing ring 15, the connecting portions 175 are positioned on one side of the outer surface 155 of the fixing ring 15, and the second ends 173 are positioned on one side of the lower surface 153 of the fixing ring 15.

The first ends 171 of the fixing members 17 extend in a direction from the outer surface 155 of the fixing ring 15 toward the inner surface 157 and to the containing area 150, to contact and fix the wafer 14 positioned on the support pedestal 13. The second ends 173 of the fixing members 17 are connected to the fixing ring 15 via the connecting shafts 185, such as via the connecting shafts 185 to connect to the connecting arms 183 on the lower surface 153 of the fixing ring 15, and also the elastic units 181 may be disposed between the second ends 173 of fixing members 17 and the lower surface 153 of the fixing ring 15.

In one embodiment of the present disclosure, the elastic units 181 may be positioned between the connecting arm 183 and the support pedestal 13, wherein each of the elastic units 181 has an end connected to the lower surface 153 of the fixing ring 15, and another end connected to a respective one of the second end 173 of the fixing members 17. The first ends 171 of the fixing members 17 will swing relative to the fixing ring 15 when pushed by the wafer 14, and then compress the elastic units 181 between the second ends 173 of the fixing members 17 and the lower surface 153 of the fixing ring 15.

In another embodiment of the present disclosure, the elastic units 181 may be positioned between the connecting arms 183 and the connecting portions 175 of the fixing members 17, wherein each of the elastic units 181 has an end connected to the lower surface 153 of the fixing ring 15, and another end connected to a respective one of the second ends 173 of the fixing members 17. When the first ends 171 of the fixing members 17 are pushed by the wafer 14, the elastic units 181 between the second ends 173 of the fixing members 17 and the lower surface 153 of the fixing ring 15 will be stretched.

The elastic units 181 generate restoring force when being compressed or stretched, which enables the fixing members 17 to press fit the wafer 14 on the support pedestal 13, thereby fixing the wafer 14 on the support pedestal 13. Also, by virtue of disposing the elastic units 181, this can further function as a cushion between the fixing members 17 and the wafer 14 contacting therewith, to prevent the wafer 14 from receiving excessive pressure from the fixing members 17, and then being damaged.

In one embodiment of the present disclosure, the wafer pre-cleaning machine 10 further includes an annular structure 16, wherein the annular structure 16 is disposed on the support pedestal 13 to surround the wafer 14. To be specific, the support pedestal 13 may include a protruding portion 131 and a bottom portion 133, wherein the protruding portion 131 is connected to the bottom portion 133, also a sectional area of the bottom portion 133 is larger than that of the protruding portion 131, and the annular structure 16 is disposed to surround the protruding portion 131 of the support pedestal 13.

The annular structure 16 may include an inner surface 161 and an outer surface 163. When the annular structure 16 is disposed to surround the protruding portion 131 of the support pedestal 13, the inner surface 161 of the annular structure 16 will contact the surface of the protruding portion 131 of the support pedestal 13, and the outer surface 163 of the annular structure 16 will contact the inner surface 157 of the fixing ring 15. For example, the outer surface 163 of the annular structure 16 may be an inclined surface, and the inner surface 157 of the fixing ring 15 may also be an inclined surface, wherein the inclined surface of the inner surface 157 of the fixing ring 15 matches the inclined surface of the outer surface 163 of the annular structure 16 with similar slope. While connecting the fixing ring 15 and the support pedestal 13, the fixing ring 15 can be guided to a locking position at the support pedestal 13, via both of the outer surface 163 and the inner surface 157.

In practical use, the support pedestal 13 may be connected to an elevating device 137, wherein the elevating device 137 is used for driving the support pedestal 13 and the wafer 14 to move relative to the fixing ring 15. Specifically, the elevating device 137 can drive the support pedestal 13 to descend to a feeding position, and transport the wafer 14 to the support pedestal 13 by a robotic arm. Then, the elevating device 137 will carry the support pedestal 13 and the wafer 14 to ascend, so as to connect the support pedestal 13 to the fixing ring 15, and the wafer 14 on the support pedestal 13 will contact the fixing members 17, and then the wafer 14 is fixed on the support pedestal 13 by the fixing members 17.

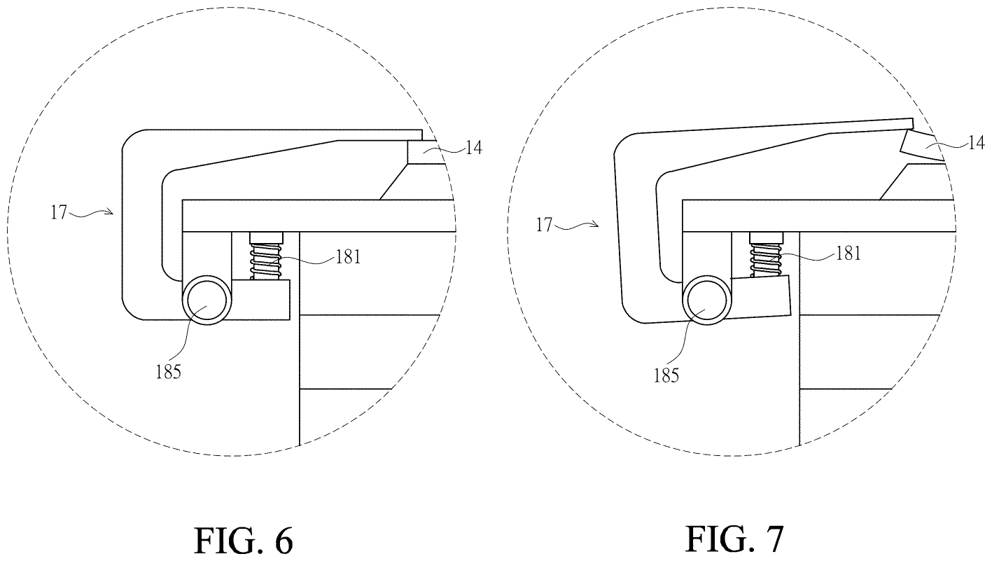

As shown in FIG. 6, the elevating device 137 drives the support pedestal 13 and a flat wafer 14 to connect to the fixing ring 15, and the fixing members 17 on the fixing ring 15 will contact and fix the wafer 14 on the support pedestal 13. Meanwhile, the fixing members 17 does not swing relative to the fixing ring 15, wherein the first ends 171 of the fixing members 17 can remain horizontal.

In contrary, as shown in FIG. 7, when the elevating device 137 drives the support pedestal 13 and a non-flat wafer 14 to connect to the fixing ring 15, the edge area of the wafer 14 will, for example, bulge upward, this will cause the edge area of the wafer 14 placed on the support pedestal 13 at a position higher than its central area. Due to the fixing members 17 of the present disclosure being disposed on the fixing ring 15 are movable components, when the bulged-up edge area of the wafer 14 is pushing the fixing members 17, the fixing members 17 will swing relative to the fixing ring 15 and the wafer 14, to avoid the pressure being applied on the wafer 14 by the fixing members 17 becomes excessive, and prevent damage to the wafer 14. In comparison, in the conventional technology, when the elevating device drives the support pedestal and the wafer to approach the fixing ring, the fixing members on the fixing ring will press on the bulged-up edge area of the wafer, and cause damage to the edge area of the wafer.

Moreover, when the fixing ring 15 of the present disclosure is connecting to the support pedestal 13, the height level of the upper surface 151 of the fixing ring 15 is lower than that of the surface of the wafer 14 supported by the support pedestal 13, and this can avoid the fixing ring 15 blocking the edge area of the wafer 14, and to prevent turbulence from forming in the edge area of the wafer 14, which can aid in improving the uniformity of the surface etching for the wafer 14.

In one embodiment of the present disclosure, the fixing ring 15 may have at least three positioning holes 152 disposed thereon, wherein the positioning holes 152 may be arrayed around the support pedestal 13 and/or the wafer 14. The chamber 11 may have at least three positioning pins (not shown) disposed therein, wherein the positioning holes 152 of the fixing ring 15 may be positioned and disposed in the containing room 12 of the chamber 11 while being aligned with the positioning pins of the chamber 11. In one embodiment of the present disclosure, a block may be disposed in the chamber 11, to support the fixing ring 15 thereby. The block may have an end formed as a round containing room for containing the support pedestal 13 and the wafer 14, and moreover, the block may have positioning pins disposed thereon, for positioning the block and the fixing ring 15.

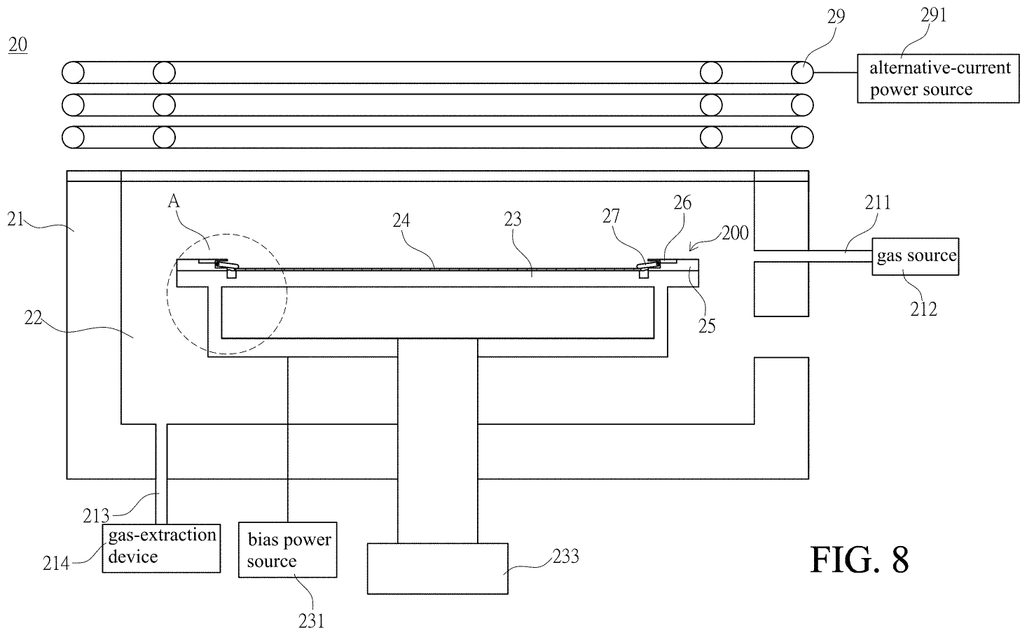

Referring to FIG. 8, which is a sectional schematic view of a wafer pre-cleaning machine 20 according to another embodiment of the present disclosure. The wafer pre-cleaning machine 20 mainly includes a chamber 21, a support pedestal 23, a swing-type wafer fixing mechanism 200 and a coil 29, wherein the chamber 21 has a containing room 22. The support pedestal 23 and the swing-type wafer fixing mechanism 200 are positioned in the containing room 22 of the chamber 21. The support pedestal 23 is used for placing at least one wafer 24, and the swing-type wafer fixing mechanism 200 is used for fixing the wafer 24 on the support pedestal 23.

The chamber 21 is disposed with at least one gas inlet end 211 and at least one gas-extraction end 213, wherein the gas inlet end 211 and the gas-extraction end 213 are fluidly connected to the containing room 22 of the chamber 21. The gas-extraction end 213 can be connected to a gas-extraction device 214, for extracting gas within the containing room 22. The gas inlet end 211 can be connected to a gas source 212, wherein the gas source 212 can be a container for storing cleaning gas, and transfer the cleaning gas into the containing room 22 via the gas inlet end 211. For example, the cleaning gas may be argon gas or other noble gas, and the gas-extraction device 214 may be a pump, and capable of extracting the gas within the containing room 22 before, during or after the pre-clean process.

The coil 29 is electrically connected to an alternative-current power source 291, wherein the alternative-current power source 291 provides an alternative current to the coil 29, and causes the coil 29 to form a magnetic field in the containing room 22 of the chamber 21. Affected by the magnetic field, the cleaning gas within the containing room 22 forms plasma, such as transforming the argon gas into the argon ions. The coil 29 and the chamber 21 are adjacent to each other, and the coil 29 is positioned above or aside of the chamber 21. The positioning of the coil 29 relative to the chamber 21 is basically just for the coil 29 to generate the magnetic field in the containing room 22 of the chamber 21 to form the plasma within the containing room 22. Therefore, the position of the coil 29 is not limited by the present disclosure.

The support pedestal 23 is used for supporting at least one wafer 24, and the support pedestal 23 is electrically connected to a bias power source 231. The bias power source 231 is used for forming a bias on the support pedestal 23, which causes the plasma to hit the wafer 24 on the support pedestal 23. The bias power source 231 may be an alternative-current power source or a direct-current power source, for example. Specifically, the support pedestal 23 may be a conductor, and the bias power source 231 is used to form negative voltage on the support pedestal 23, to attract the positively charged argon ions (Ar+) and cause the argon ions to hit the wafer 24 on the support pedestal 23, thereby removing the oxide layer or oxide on surface of the wafer 24, in order to pre-clean the wafer 24.

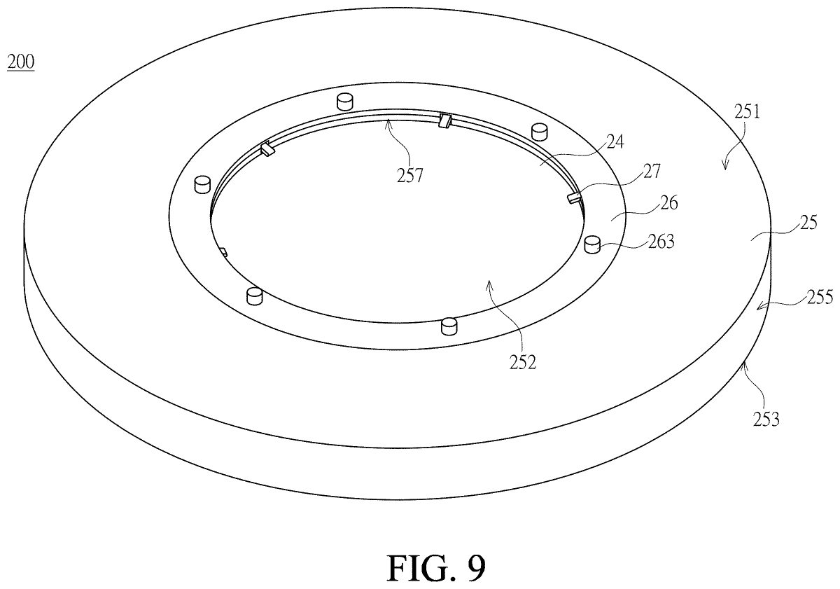

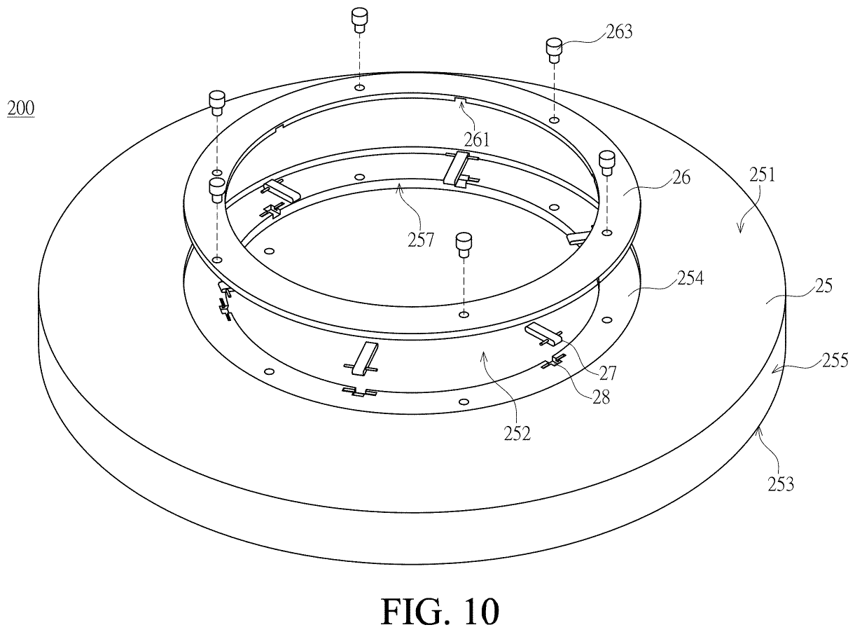

The swing-type wafer fixing mechanism 200 includes a fixing ring 25, a plurality of swing-type fixing members 27 and a lid ring 26, as shown in FIG. 9 and FIG. 10. The fixing ring 25 is annular, and includes a containing area 252 and a plurality of connecting slots 28. The containing area 252 is positioned in inner side of the fixing ring 25, for containing the wafer 24 supported by the support pedestal 23, and the plural connecting slots 28 is disposed to surround the containing area 252.

The plurality of swing-type fixing members 27 are respectively disposed in the connecting slots 28 of the fixing ring 25, and are able to swing relative to the fixing ring 25 in the connecting slots 28. The lid ring 26 is disposed on the fixing ring 25, to position the swing-type fixing members 27 between the fixing ring 25 and the lid ring 26, and to restrain the swing-type fixing members 27 within the connecting slots 28.

Specifically, the fixing ring 25 includes an upper surface 251, a lower surface 253, an outer surface 255 and an inner surface 257. The upper surface 251 and the lower surface 253 may be annular structures, and the outer surface 255 and inner surface 257 are side surfaces that interconnect the upper surface 251 and the lower surface 253. The outer surface 255 and the inner surface 257 are approximately circular from a top view, wherein a radius of the outer surface 255 is greater than that of the inner surface 257. The inner side of the inner surface 257 of the fixing ring 25 can form a containing area 252, wherein the containing area 252 may be cylindrical or disk-like, and the support pedestal 23 and the wafer 24 may be positioned in the containing area 252 of the fixing ring 25.

The connecting slots 28 are disposed on the upper surface 251 of the fixing ring 25, and close to the containing area 252. The swing-type fixing members 27 are respectively disposed in each of the connecting slots 28, and swingable relative to the fixing ring 25 in the connecting slots 28, such as swinging back-and-forth in the axial direction of the fixing ring 25. The number of the swing-type fixing members 27 and the connecting slots 28 may be three or more.

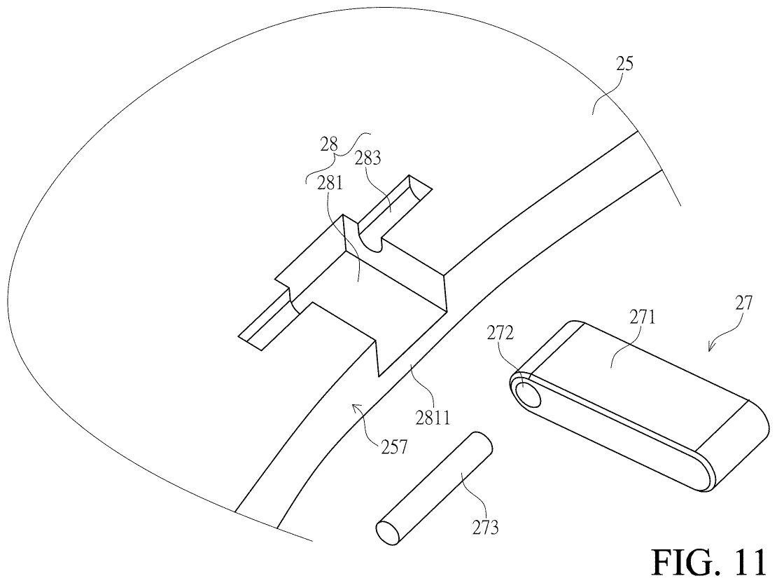

In one embodiment of the present disclosure, as shown in FIG. 11, each of the connecting slots 28 may include a swing slot 281 and at least one shaft slot 283. For example, the number of shaft slot 283 may be two and the two shaft slots 283 are respectively disposed on two sides of the swing slot 281, wherein the shaft slots 283 are substantially perpendicular to the swing slot 281. Moreover, the depth of the swing slot 281 may be greater than that of the shaft slot 283, which enables the swing-type fixing members 27 to swing relative to the fixing ring 25 in the swing slots 281.

Each of the swing-type fixing members 27 includes a fixing portion 271 and at least one shaft 273. The fixing portion 271 and the shaft 273 may be two independent components, wherein the fixing portion 271 may be disposed with a through hole 272, and the shaft 273 is connected to the fixing portion 271 by passing through the through hole 272. In another embodiment of the present disclosure, the fixing portion 271 and the shaft 273 may be integrally formed as one component.

The shafts 273 of the swing-type fixing members 27 can be disposed in the shaft slots 283 of the connecting slots 28. The fixing portions 271 of the swing-type fixing members 27 are positioned in the swing slots 281 of the connecting slots 28. Sectional areas of the shafts 273 are slightly less than that of the shaft slots 283, and are rotatable relative to the shaft slots 283, wherein the shafts 273 and the shaft slots 283 may, for example, be cylindrical. Volumes of the fixing portions 271 are smaller than that of the swing slots 281, so the fixing portions 271 are swingable in the swing slots 281. To be specific, the fixing portions 271 of the swing-type fixing members 27 can swing relative to the fixing ring 25 in the swing slots 281, with the shafts 273 as axles.

When the swing-type fixing members 27 are disposed in the connecting slots 28, the fixing portions 271 will partially protrude from the inner surface 257 of the fixing ring 25, and be in the containing area 252. In one embodiment of the present disclosure, an appearance of the fixing ring 25 is approximately annular, and the swing-type fixing members 27 extend along a radical direction of the fixing ring 25.

When the fixing ring 25 is connected to the support pedestal 23, the support pedestal 23 and the supported wafer 24 will be in the containing area 252, and the swing-type fixing members 27 disposed on the fixing ring 25 will contact an upper surface of the wafer 24 which is supported by the support pedestal 23, thereby fixing the wafer 24 on the support pedestal 23.

In practical use, the support pedestal 23 may be connected to an elevating device 233, as shown in FIG. 8, wherein the elevating device 233 is used for driving the support pedestal 23 and the wafer 24 to move relative to the fixing ring 25. To be specific, the elevating device 233 can drive the support pedestal 23 to descend into a feeding position, and transport the wafer 24 to the support pedestal 23 via a robotic arm, thereafter the elevating device 233 will drive the support pedestal 23 and the wafer 24 to ascend, and thereby connecting the support pedestal 23 to the fixing ring 25. Then, the swing-type fixing members 27 will contact the support pedestal 23. The swing-type fixing members 27 will then swing downward due to the effect of gravity, and apply a downward force to the wafer 24 below, to fix the wafer 24 on the support pedestal 23.

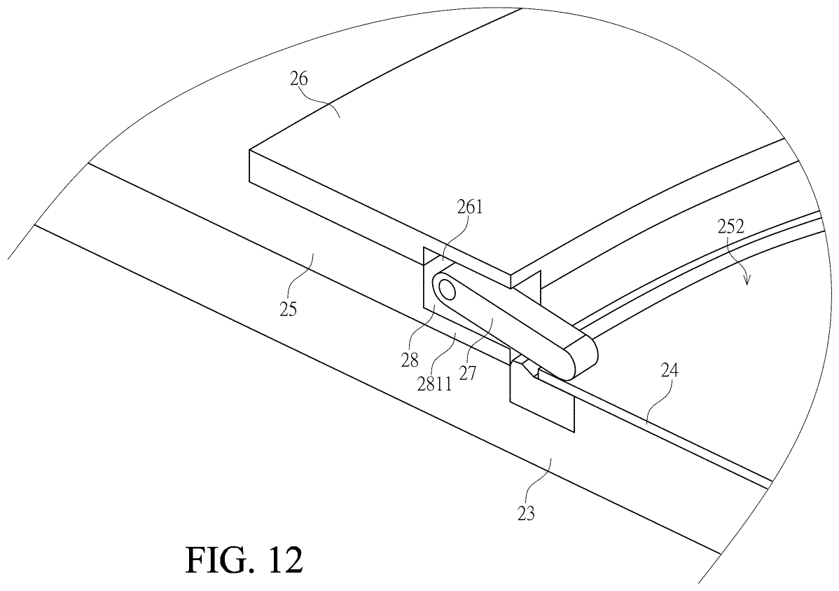

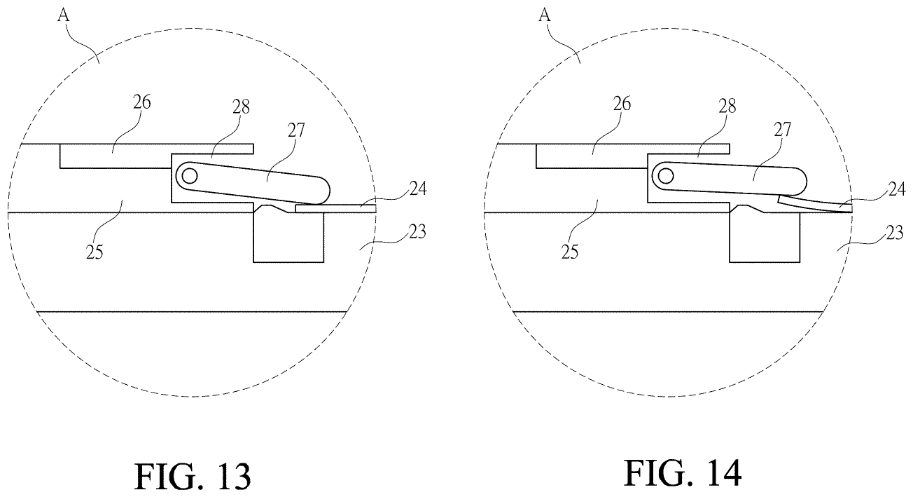

As shown in FIG. 12 and FIG. 13, the elevating device 233 drives the support pedestal 23 and a flat wafer 24 to connect to the fixing ring 25, and the swing-type fixing members 27 on the fixing ring 25 will contact and fix the wafer 24 on the support pedestal 23, meanwhile the swing-type fixing members 27 may not swing upward relative to the fixing ring 25.

In contrary, as shown in FIG. 14, when the elevating device 233 drives the support pedestal 23 and a non-flat wafer 24 to connect the fixing ring 25, the edge area of the wafer 24 will likely to bulge up which causes the edge area of the wafer 24 to be in a position higher than the central area. Because the swing-type fixing members 27 disposed on the fixing ring 25 of the present disclosure are movable components, when the bulged-up edge area on the wafer 24 is pushing the swing-type fixing members 27, the swing-type fixing members 27 in the connecting slots 28 will swing upward relative to the fixing ring 25 and the wafer 24, to prevent the pressure being applied on the wafer 24 by the swing-type fixing members 27 from becoming excessive, and to prevent damage of the wafer 24. On the contrary, in the convention technology, when the elevating device drives the support pedestal and the wafer to approach the fixing ring, the fixing members on the fixing ring will press against the bulged-up edge area of the wafer, and then cause damage to the edge area of the wafer.

In practical use, swing-type fixing members 27 with suitable weights may be chosen, in accordance with a maximum-tolerable external force of the wafer 24 and a critical external force sufficient to move the wafer 24. This allows the swing-type fixing members 27 to fix the wafer 24 on the support pedestal 23, without damaging the wafer 24.

In a different embodiment, the swing-type wafer fixing mechanism 200 may be configured as that whenever the elevating device 233 drives the support pedestal 23 and the wafer 24 to connect to the fixing ring 25, the swing-type fixing members 27 will always swing upward, whether the wafer 24 is flat or not. To be specific, when the wafer 24 is flat, the swing-type fixing members 27 will swing upward in a small angle, and when the wafer 24 is non-flat, the swing-type fixing members 27 will swing upward in a large angle.

In one embodiment of the present disclosure, a block portion 2811 may be disposed in each of the swing slots 281 of the fixing ring 25, as shown in FIG. 11 and FIG. 12. For example, the block portion 2811 is positioned beneath the swing-type fixing members 27, for restraining swing angles of the swing-type fixing members 27 relative to the fixing ring 25, to prevent the swing-type fixing members 27 from falling straight down.

In one embodiment of the present disclosure, a plurality of cavities 261 may also be disposed on the lid ring 26, as shown in FIG. 10 and FIG. 12, wherein the number of the cavities 261 is same as that of the connecting slots 28 and the swing-type fixing members 27. When the lid ring 26 is mounted on the fixing ring 25, the cavities 261 of the lid ring 26 can be arranged corresponding to the connecting slots 28 of the fixing ring 25, and the swing-type fixing members 27 are positioned between the connecting slots 28 on the fixing ring 25 and the cavities 261 on the lid ring 26. The swing-type fixing members 27 can thus swing within a space formed by the connecting slots 28 and the cavities 261.

In one embodiment of the present disclosure, the upper surface 251 of the fixing ring 25 may also be disposed with an annular cavity 254, and then the lid ring 26 may be embedded into the annular cavity 254 of the fixing ring 25. The lid ring 26 may be further fastened on the fixing ring 25 by fastening bolts 263.

The above disclosure is only the preferred embodiment of the present disclosure, and not used for limiting the scope of the present disclosure. All equivalent variations and modifications on the basis of shapes, structures, features and spirits described in claims of the present disclosure should be included in the claims of the present disclosure.

We claim:

1. A wafer pre-cleaning machine, comprising:
a chamber comprising a containing room;
at least one gas-extraction end fluidly connected to the containing room of the chamber, for extracting a gas within the containing room;
at least one gas inlet end fluidly connected to the containing room of the chamber, for transferring a cleaning gas to the containing room;
at least one coil disposed adjacent to the chamber and electrically connected to an alternative-current power source, wherein the at least one coil is for forming a magnetic field in the containing room to transform the cleaning gas into plasma;
a support pedestal positioned in the containing room for supporting at least one wafer, wherein the support pedestal is electrically connected to a bias power source to form a bias on the support pedestal so as to cause the plasma to hit the wafer on the support pedestal, to clean the wafer supported by the support pedestal;
at least one fixing ring disposed in the containing room and comprising a containing area, wherein the wafer supported by the support pedestal is in the containing area;
a plurality of fixing members, each of the fixing members being connected to the fixing ring respectively via a connecting shaft to swing relative to the fixing ring with the connecting shaft as axis, wherein the fixing members contact a surface of the wafer and fix the wafer on the support pedestal; and
a plurality of elastic units, each of the elastic units being positioned between a respective one of the fixing members and the fixing ring, wherein when the wafer applies a push force on the fixing members, the fixing members swing relative to the fixing ring and cause the elastic units to deform.

2. The wafer pre-cleaning machine as claimed in claim 1, wherein:
the fixing ring comprises a plurality of connecting arms;
the connecting arms are positioned on a lower surface of the fixing ring;
the fixing members are connected to the connecting arms via the connecting shafts; and
each of the connecting arms comprises a block portion for restraining a swing angle of each of the fixing members relative to the fixing ring.

3. The wafer pre-cleaning machine as claimed in claim 2, wherein:
each of the fixing members has a U-shaped appearance, and comprises a first end, a second end, and a connecting portion;
the connecting portion comprises two ends respectively connected to the first end and the second end;
the first end is positioned in a side of an upper surface of the fixing ring;
the second end is positioned in a side of the lower surface of the fixing ring, and the second ends of the fixing members are connected to the connecting arms via the connecting shafts.

4. The wafer pre-cleaning machine as claimed in claim 3, wherein:
the elastic units are positioned between the second ends of the fixing members and the lower surface of the fixing ring; and
the first ends of the fixing members extend to the containing area of the fixing ring, for fixing the wafer positioned in the containing area on the support pedestal.

5. The wafer pre-cleaning machine as claimed in claim 1, further comprising an annular structure disposed on the support pedestal, the annular structure being disposed to surround the support pedestal, and the fixing ring being positioned around the annular structure, wherein the annular structure comprises an inner surface connected to the support pedestal, the annular structure comprises an outer surface disposed with an inclined surface, and the fixing ring comprises an inner surface disposed with an inclined surface that matches the inclined surface of the outer surface of the annular structure.

6. The wafer pre-cleaning machine as claimed in claim 1, wherein the fixing ring comprises an upper surface positioned at a height level lower than that of a surface of the wafer supported by the support pedestal.

7. The wafer pre-cleaning machine as claimed in claim 1, wherein the fixing ring comprises a plurality of positioning holes, and the positioning holes are disposed to surround the support pedestal.

8. A wafer fixing mechanism, comprising:
a fixing ring comprising a containing area for containing a wafer;
a plurality of fixing members, each of the fixing members being connected to the fixing ring respectively via a connecting shaft to swing relative to the fixing ring with the connecting shaft as an axis, wherein the fixing members are for contacting and fixing the wafer; and
a plurality of elastic units, each of the elastic units being positioned between a respective one of the fixing members and the fixing ring, wherein when the wafer applies a push force on the fixing members, the fixing members swing relative to the fixing ring and cause the elastic units to deform.

9. The wafer fixing mechanism as claimed in claim 8, wherein:
the fixing ring comprises a plurality of connecting arms;
the connecting arms are positioned on a lower surface of the fixing ring;
the fixing members are connected to the connecting arms via the connecting shafts; and
each of the connecting arms comprises a block portion for restraining a swing angle of each of the fixing members relative to the fixing ring.

10. The wafer fixing mechanism as claimed in claim 8, wherein:
each of the fixing members has a U-shaped appearance, and comprises a first end, a second end, and a connecting portion;
the connecting portion comprises two ends respectively connected to the first end and the second end;
the first end is positioned in a side of an upper surface of the fixing ring; and
the second end is positioned in a side of an lower surface of the fixing ring, and the second ends of the fixing members are connected to the connecting arms via the connecting shafts, wherein the elastic units are positioned between the second ends of the fixing members and the lower surface of the fixing ring.

11. A wafer pre-cleaning machine, comprising:
a chamber comprising a containing room;
at least one gas-extraction end fluidly connected to the containing room of the chamber, for extracting a gas within the containing room;
at least one gas inlet end fluidly connected to the containing room of the chamber, for transferring a cleaning gas to the containing room;
at least one coil disposed adjacent to the chamber and electrically connected to an alternative-current power source, wherein the at least one coil is for forming a magnetic field in the containing room to transform the cleaning gas into plasma;
a support pedestal positioned in the containing room for supporting at least one wafer, wherein the support pedestal is electrically connected to a bias power source to form a bias on the support pedestal so as to cause the plasma to hit the wafer on the support pedestal, to clean the wafer supported by the support pedestal;
at least one fixing ring disposed in the containing room and comprising a containing area and a plurality of connecting slots, wherein the containing area is in the fixing ring for containing the wafer supported by the support pedestal, and the connecting slots are disposed to surround the containing area;
a plurality of the swing-type fixing members respectively disposed in the connecting slots of the fixing ring to swing in the connecting slots relative to the fixing ring, wherein the swing-type fixing members swing downward by effect of gravity and contact an upper surface of the wafer to fix the wafer on the support pedestal; and
a lid ring disposed on the fixing ring to position the swing-type fixing members between the fixing ring and the lid ring and to restrain the swing-type fixing members in the connecting slots.

12. The wafer pre-cleaning machine as claimed in claim 11, wherein each of the swing-type fixing members comprises a shaft and a fixing portion, the shaft is connected to the fixing portion, to allow the fixing portions of the swing-type fixing members in the connecting slots swing relative to the fixing ring with the shafts as axes.

13. The wafer pre-cleaning machine as claimed in claim 12, wherein:
each of the connecting slots comprises a swing slot and a shaft slot;
the shafts of the swing-type fixing members are disposed in the shaft slots of the connecting slots; and
the fixing portions of the swing-type fixing members are positioned in the swing slots of the connecting slots.

14. The wafer pre-cleaning machine as claimed in claim 13, wherein when the wafer pushes upward against the swing-type fixing members, the fixing portions of the swing-type fixing members in the swing slots of the connecting slots swing upward relative to the fixing ring, and the shafts of the swing-type fixing members rotate in the shaft slots of the connecting slots.

15. The wafer pre-cleaning machine as claimed in claim 11, wherein:
the lid ring includes a plurality of cavities; and
the positions and the number of the cavities are relative to the positions and the number of the connecting slots of the fixing ring; and
the swing-type fixing members are positioned in the cavities and in the connecting slots.

16. A wafer fixing mechanism, comprising:
at least one fixing ring comprising a containing area and a plurality of connecting slots, wherein the containing area is in the at least one fixing ring for containing a wafer, and the connecting slots are disposed to surround the containing area;
a plurality of the swing-type fixing members respectively disposed in the connecting slots of the fixing ring, wherein the swing-type fixing members swing downward by effect of gravity and contact an upper surface of the wafer, and when the wafer applies a push force on the swing-type fixing members, the swing-type fixing members in the connecting slots swing upward relative to the fixing ring; and
a lid ring disposed on the fixing ring to position the swing-type fixing members between the fixing ring and the lid ring and to restrain the swing-type fixing members in the connecting slots.

17. The wafer fixing machine as claimed in claim 16, wherein each of the swing-type fixing members comprises a shaft and a fixing portion, the shaft is connected to the fixing portion, to allow the fixing portions of the swing-type fixing members in the connecting slots swing relative to the fixing ring with the shafts as axes.

18. The wafer fixing machine as claimed in claim 17, wherein:
each of the connecting slots comprises a swing slot and a shaft slot;
the shafts of the swing-type fixing members are disposed in the shaft slots of the connecting slots; and
the fixing portions of the swing-type fixing members are positioned in the swing slots of the connecting slots.

19. The wafer fixing machine as claimed in claim 18, wherein when the wafer pushes upward against the swing-type fixing members, the fixing portions of the swing-type fixing members in the swing slots swing upward relative to the fixing ring, and the shafts of the swing-type fixing members rotate in the shaft slots.

20. The wafer fixing machine as claimed in claim 16, wherein:
the lid ring comprises a plurality of cavities;
the positions and the number of the cavities are relative to the positions and the number of the connecting slots of the fixing ring; and
the swing-type fixing members are positioned in the cavities and in the connecting slots.
